(19) United States
(12) Patent Application Publication
(10) Pub. No.: US 2022/0415735 A1
(43) Pub. Date: Dec. 29, 2022

(54) POWER MODULE AND POWER CONVERSION DEVICE

(71) Applicant: Mitsubishi Electric Corporation, Tokyo (JP)

(72) Inventors: Kozo HARADA, Tokyo (JP); Ken SAKAMOTO, Tokyo (JP); Yoshihiro YAMAGUCHI, Tokyo (JP)

(73) Assignee: Mitsubishi Electric Corporation, Tokyo (JP)

(21) Appl. No.: 17/778,871

(22) PCT Filed: Jan. 17, 2020
(86) PCT No.: PCT/JP2020/001557

§ 371 Date: May 23, 2022

(51) Int. Cl. H01L 23/28; H01L 23/04; H01L 25/07; H01L 23/00

(52) U.S. Cl. CPC H01L 23/28; H01L 23/04; H01L 25/07; H01L 24/32; H01L 24/73; H01L 2224/32225; H01L 2224/73265; H01L 2924/181

(57) ABSTRACT

A power module includes an insulating substrate, a case member, a power semiconductor element, a base member, a sealing member, and an adhesive member. The insulating substrate has a first surface and a second surface opposite to the first surface. The case member surrounds the insulating substrate when viewed in a direction perpendicular to the first surface. The power semiconductor element faces the first surface. The base member faces the second surface. The sealing member seals the power semiconductor element and the insulating substrate and is in contact with the case member. The adhesive member fixes the base member and the case member, and surrounds the insulating substrate when viewed in the direction perpendicular to the first surface.

### TECHNICAL FIELD

The present disclosure relates to a power module and a power conversion device.

### BACKGROUND ART

A type of semiconductor element in which a current path is formed in a vertical direction of the element so as to handle a high voltage and a large amount of current is generally referred to as “power semiconductor element”. Examples of types of power semiconductor elements include an IGBT (Insulated Gate Bipolar Transistor), a MOSFET (Metal Oxide Semiconductor Field Effect Transistor), a bipolar transistor, a diode, and the like. A device in which such a power semiconductor element is mounted on a circuit board and is packaged with a sealing resin is generally referred to as “power module”. Such a power module is used in a wide range of fields such as industrial devices, automobiles, railways, and the like. In recent years, in response to improved performance of a device having the power module mounted thereon, demands arise in improved performance of the power module such as increased rated voltage and rated current as well as an increased use temperature range (specifically, higher and lower temperatures).

A mainly employed package structure of the power module is called a case type. In the case type power module, the power semiconductor element is mounted on a heat radiation base plate with an insulating substrate being interposed therebetween. A case is adhered to the base plate. The power semiconductor element is connected to a main electrode. A bonding wire is used to connect the power semiconductor element and the main electrode to each other. Generally, in order to prevent insulation failure upon application of high voltage, a silicone gel, an epoxy resin, or the like is used as a sealing resin for the power module.

In the case type power module described in Japanese Patent Laying-Open No. 2004-235566 (PTL 1), a portion of an adhesion surface between the case and the base plate is connected straightly to an interface between the sealing resin and the base plate. Moreover, the inner end portion of the adhesion surface between the base plate and the case is located at the same height as that of a surface of the base plate facing the insulating substrate. In the case type power module described in Japanese Patent Laying-Open No. 2019-54069 (PTL 2), the inner end portion of an adhesion surface between the base plate and the case is located at the same height as that of a surface of the base plate facing the insulating substrate.

### CITATION LIST

### Patent Literature

PTL 1: Japanese Patent Laying-Open No. 2004-235566

PTL 2: Japanese Patent Laying-Open No. 2019-54069

### SUMMARY OF INVENTION

### Technical Problem

In recent years, in response to improved performance of a device used, demands arise in increased rated voltage and rated current of the power module as well as an increased range of use temperature, with the result that it has become very important to achieve both heat radiation and insulation. In the power module, which is constituted of various members, warpage and deformation resulting from a temperature change occur due to a difference in thermal expansion coefficient among the constituent members. In particular, in a reliability test such as a temperature cycle test, warpage of the power module greatly differs between a case of a low temperature and a case of a high temperature. A range of variation of the warpage of the power module (that is, a difference between the warpage of the power module at high temperature and the warpage of the power module at low temperature) is the largest at the outer end portion of the adhesion surface between the base plate and the case of the power module.

In order to avoid leakage of the sealing resin during a manufacturing process of the power module, it is required to adhere the base plate and the case to each other with no gap being formed therebetween, Therefore, an adhesive agent having excellent shape stability and low stress, such as a silicone resin, is used to adhere the base plate and the case to each other. Generally, however, such an adhesive agent composed of a silicone resin having low stress has low adhesive force and is likely to be detached. Therefore, in the reliability test such as a temperature cycle test of the power module, detachment may occur from the outer end portion of the adhesion surface between the base plate and the case.

In the power module described in PTL 1, a portion of the adhesion surface between the case and the base plate is connected straightly to the interface between the sealing resin and the base plate. When the adhesion surface between the case and the base plate is connected straightly to the interface between the sealing resin and the base member, detachment at the adhesion surface between the case and the base member is progressed toward the inner side straightly, with the result that detachment is likely to occur at the interface between the base member and the sealing resin.

Further, in each of the power modules described in PTL 1 and PTL 2, the inner end portion of the adhesion surface between the base plate and the case is located at the same height as that of the surface of the base plate facing the insulating substrate. When the inner end portion of the adhesion surface between the case and the base member is located at the same height as that of the adhesion surface between the sealing resin and the surface of the base member facing the insulating substrate, detachment having occurred at the outer end portion of the adhesion surface is progressed to the inner end portion of the adhesion surface and then reaches just below the insulating substrate. When the detachment reaches just below the insulating substrate, insulation failure of the power module may be caused.

The present disclosure has been made to solve the above-described problem, and has an object to suppress insulation failure of a power module by suppressing progress of detachment.

### SOLUTION TO PROBLEM

A power module according to the present disclosure includes an insulating substrate, a case member, a power semiconductor element, a base member, a sealing member, and an adhesive member. The insulating substrate has a first surface and a second surface opposite to the first surface. The case member surrounds the insulating substrate when viewed in a direction perpendicular to the first surface. The power semiconductor element faces the first surface. The base member faces the second surface. The sealing member seals the power semiconductor element and the insulating substrate and is in contact with the case member. The adhesive member fixes the base member and the case member and surrounds the insulating substrate when viewed in the direction perpendicular to the first surface. The base member has a third surface that is in contact with the adhesive member, a fourth surface that is contiguous to the third surface and that is in contact with the sealing member, and a fifth surface that faces the second surface. In a direction perpendicular to the fifth surface, the inner end portion of the third surface is located at a height different from a height of the fifth surface. The third surface is inclined with respect to the fourth surface.

### ADVANTAGEOUS EFFECTS OF INVENTION

According to the power module of the present disclosure, insulation failure of the power module can be suppressed by suppressing progress of detachment.

### BRIEF DESCRIPTION OF DRAWINGS

FIG. 1 is a schematic cross sectional view showing a configuration of a power module according to a first embodiment.

FIG. 2 is a schematic plan view showing the configuration of the power module according to the first embodiment.

FIG. 3 is an enlarged schematic cross sectional view of a region III in FIG. 1.

FIG. 4 is a schematic cross sectional view showing a configuration of a power module according to a second embodiment.

FIG. 5 is an enlarged schematic cross sectional view of a region V in FIG. 4.

FIG. 6 is a schematic cross sectional view showing a configuration of a power module according to a third embodiment.

FIG. 7 is a schematic cross sectional view showing a configuration of a power module according to a fourth embodiment.

FIG. 8 is a schematic cross sectional view showing a configuration of a power module according to a fifth embodiment.

FIG. 9 is a schematic cross sectional view showing a configuration of a power module according to a sixth embodiment.

FIG. 10 is a schematic cross sectional view showing a configuration of a power module according to a seventh embodiment.

FIG. 11 is a schematic cross sectional view showing a configuration of a power module according to an eighth embodiment.

FIG. 12 is a schematic cross sectional view showing a configuration of a power module according to a ninth embodiment.

FIG. 13 is a block diagram showing a configuration of a power conversion system including a power conversion device according to a tenth embodiment.

FIG. 14 is a schematic partial cross sectional view showing a configuration in which warpage occurs in a conventional case type power module.

### DESCRIPTION OF EMBODIMENTS

### First Embodiment

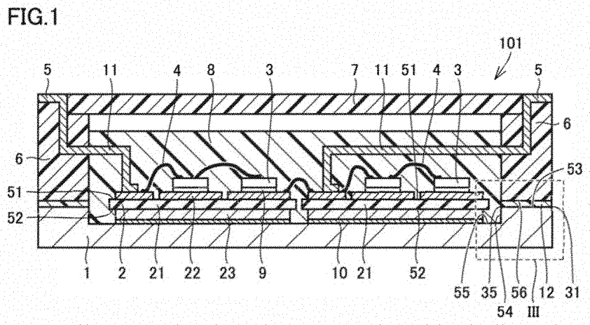

FIG. 1 is a schematic cross sectional view showing a configuration of a power module 101 according to a first embodiment. As shown in FIG. 1, power module 101 according to the first embodiment mainly includes insulating substrates 21, first metal layers 22, second metal layers 23, a case member 6, power semiconductor elements 3, a base member 1, a sealing member 8, an adhesive member 12, bonding wires 4, external terminals 5, a cover member 7, first joining layers 9, second joining layers 10, and main electrodes 11.

Each of insulating substrates 21 is composed of a ceramic such as an aluminum oxide, an aluminum nitride, or a silicon nitride, for example. Insulating substrate 21 may be composed of, for example, an epoxy resin or the like. Insulating substrate 21 has a first surface 51 and a second surface 52. Second surface 52 is second surface 52 opposite to first surface 51. First metal layer 22 is disposed on first surface 51. Second metal layer 23 is disposed on second surface 52. The material of each of first metal layer 22 and second metal layer 23 is, for example, a metal such as copper or aluminum. First metal layer 22 forms a wiring pattern.

Each of power semiconductor elements 3 is, for example, a semiconductor element for power control, such as a MOSFET or an IGBT. Power semiconductor element 3 may be, for example, a reflux diode or the like. The number of power semiconductor elements 3 is more than or equal to 1. Bonding wire 4 electrically connects two power semiconductor elements 3 to each other, for example. The wire diameter of bonding wire 4 is, for example, more than or equal to 0.1 mm and less than or equal to 0.5 mm. Bonding wire 4 is composed of, for example, an aluminum alloy or a copper alloy. Power semiconductor element 3 and external terminal 5 are electrically connected to each other via bonding wire 4.

Power semiconductor element 3 is joined to first metal layer 22 with first joining layer 9 being interposed therebetween. First joining layer 9 is located between power semiconductor element 3 and first metal layer 22 in a direction perpendicular to first surface 51. Second metal layer 23 is joined to base member 1 with second joining layer 10 being interposed therebetween. Second joining layer 10 is located between second metal layer 23 and base member 1 in a direction perpendicular to second surface 52.

The material of each of first joining layer 9 and second joining layer 10 is, for example, a solder but is not limited to the solder. The material of each of first joining layer 9 and second joining layer 10 may be, for example, a sintered silver, a conductive adhesive agent, or the like. Each of first joining layer 9 and second joining layer 10 may be formed by liquid-phase diffusion bonding.

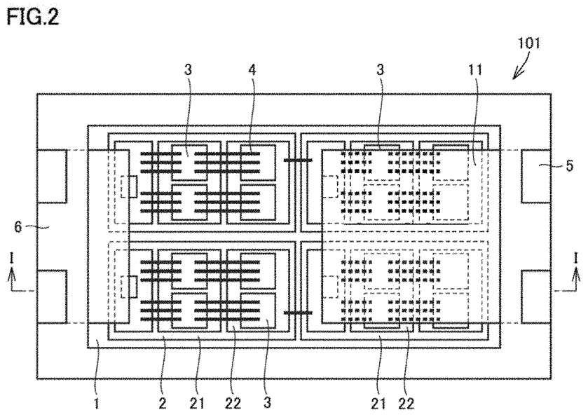

FIG. 2 is a schematic plan view showing the configuration of power module 101 according to the first embodiment. In FIG. 2, cover member 7 is not illustrated. As shown in FIG. 2, main electrode 11 may have a rectangular shape when viewed in the direction perpendicular to first surface 51. Main electrode 11 may be disposed to overlap with the plurality of power semiconductor elements 3 when viewed in the direction perpendicular to first surface 51. Main electrode 11 may be disposed to overlap with at least a portion of first metal layer 22 when viewed in the direction perpendicular to first surface 51. It should be noted that power module 101 according to the first embodiment may have no main electrode 11. For example, power semiconductor element 3 and external terminal 5 may be electrically connected to each other using bonding wire 4 or a bonding ribbon (not shown) without using main electrode 11.

As shown in FIG. 2, case member 6 is provided along the outer periphery of base member 1 when viewed in the direction perpendicular to first surface 51. Case member 6 has a shape of loop. Case member 6 surrounds insulating substrates 21 when viewed in the direction perpendicular to first surface 51. Case member 6 surrounds power semiconductor elements 3 when viewed in the direction perpendicular to first surface 51. Case member 6 is adhered to base member 1 using adhesive member 12. The material of case member 6 is, for example, a PPS (polyphenylene sulfide) resin or PBT (polybutylene terephthalate) resin.

Adhesive member 12 fixes base member 1 and case member 6. Even when a difference in flatness between a surface of case member 6 to be adhered and a surface of base member 1 to be adhered causes formation of a large gap between the surfaces, adhesive member 12 desirably has excellent shape stability and stress relaxation property so as to fill the gap. The material of adhesive member 12 is, for example, a silicone resin. Adhesive member 12 surrounds insulating substrate 21 when viewed in the direction perpendicular to first surface 51. Adhesive member 12 is provided on base member 1. Adhesive member 12 is located between base member 1 and case member 6 in the direction perpendicular to first surface 51.

Each of external terminals 5 is constituted of, for example, a plate-like electrode composed of copper. External terminal 5 is formed in the case by insert molding or outsert molding. External terminal 5 is used for input and output of current and voltage. External terminal 5 is electrically connected to first metal layer 22 on insulating substrate 21 via main electrode 11. A portion of external terminal 5 may be provided on case member 6.

Sealing member 8 is provided in a region between case member 6 and base member 1. Sealing member 8 seals power semiconductor element 3 and insulating substrate 21. Sealing member 8 seals bonding wire 4. Sealing member 8 is provided up to a height at which the whole of power semiconductor elements 3 and the whole of bonding wires 4 are sealed, for example. Sealing member 8 may be separated from cover member 7. Sealing member 8 is in contact with case member 6. Sealing member 8 is in contact with base member 1. Sealing member 8 ensures insulation inside power module 101. The material of sealing member 8 is, for example, a resin.

Cover member 7 is installed on case member 6. Cover member 7 separates the inside and outside of power module 101 from each other to prevent dust or the like from entering the inside of power module 101. Cover member 7 is fixed to case member 6 using, for example, an adhesive agent (not shown) or a screw (not shown). When an adverse effect by the dust or the like is small due to a specification of sealing member 8 or the like, no cover member 7 may be installed.

As shown in FIG. 1, power semiconductor element 3 faces first surface 51. First surface 51 may be located between power semiconductor element 3 and second surface 52 in the direction perpendicular to first surface 51. Base member 1 faces second surface 52. Second surface 52 may be located between first surface 51 and base member 1 in the direction perpendicular to second surface 52.

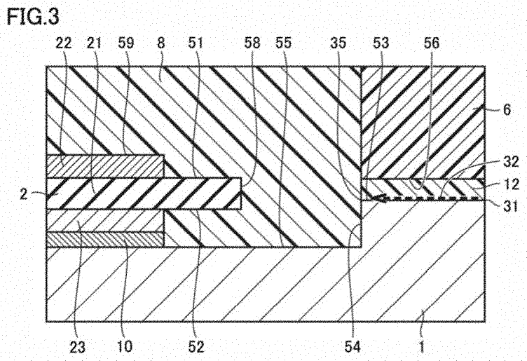

FIG. 3 is an enlarged schematic cross sectional view of a region III in FIG. 1. As shown in FIG. 3, base member 1 has a third surface 53, a fourth surface 54, and a fifth surface 55. Third surface 53 is in contact with adhesive member 12. Third surface 53 may be separated from sealing member 8. Fourth surface 54 is contiguous to third surface 53. Fourth surface 54 is in contact with sealing member 8. Fifth surface 55 faces second surface 52. Fifth surface 55 may be contiguous to fourth surface 54.

Third surface 53 is inclined with respect to fourth surface 54. From another viewpoint, it can be said that fourth surface 54 is not located in a plane extending along third surface 53 straightly. Third surface 53 is inclined at an angle of substantially 90° with respect to fourth surface 54, for example. When viewed in the direction perpendicular to fifth surface 55, fifth surface 55 is surrounded by third surface 53. Fourth surface 54 and fifth surface 55 form a recess of base member 1. Fourth surface 54 is an inner peripheral surface of the recess. Fifth surface 55 is a bottom surface of the recess.

Inner end portion 35 of third surface 53 is located at a height different from that of fifth surface 55 in the direction perpendicular to fifth surface 55. Inner end portion 35 of third surface 53 is a boundary portion between third surface 53 and fourth surface 54. Inner end portion 35 of third surface 53 is located on the case member 6 side with respect to fifth surface 55 in the direction perpendicular to fifth surface 55. Case member 6 has a sixth surface 56 in contact with adhesive member 12. Sixth surface 56 faces third surface 53. Adhesive member 12 is located between third surface 53 and sixth surface 56. Third surface 53 is located between sixth surface 56 and fifth surface 55 in the direction perpendicular to fifth surface 55. Third surface 53 may be located between first surface 51 and second surface 52 or may be located between fifth surface 55 and second surface 52 in the direction perpendicular to fifth surface 55.

Next, functions and effects of power module 101 according to the first embodiment will be described.

In response to improved performance of a device including power module 101, the temperature of the use environment is increased and the rated voltage and the rated current are also increased. Therefore, warpage of power module 101 occurs due to an influence of a difference in thermal expansion between the constituent members. Generally, the linear expansion coefficient of each of the constituent members used in power module 101 is in a range of more than or equal to 3 ppm/K and less than or equal to 25 ppm/K.

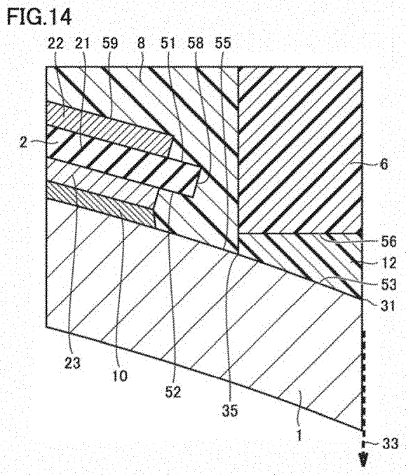

FIG. 14 is a schematic partial cross sectional view showing a configuration in which warpage occurs in a conventional case type power module. A variation of the warpage due to a temperature change is the largest at an end portion of power module 101. As shown in FIG. 14, when the center of the power module is warped to protrude upward, tensile stress is applied in the vicinity of the end portion of base member 1 in a direction of a second arrow 33. An outer end portion 31 of adhesive member 12 becomes a starting point of detachment of adhesive member 12. Adhesive member 12 is generally a silicone resin having low adhesion strength. Therefore, the detachment having occurred is facilitated to be progressed from outer end portion 31 of the adhesion surface to inner end portion 35 of the adhesion surface.

When the adhesion surface of adhesive member 12 is connected straightly to the interface between sealing member 8 and base member 1, the detachment at the adhesion surface between adhesive member 12 and base member 1 is progressed toward the inner side straightly, with the result that detachment is likely to occur at the interface between base member 1 and sealing member 8.

Further, when inner end portion 35 of the adhesion surface between adhesive member 12 and base member 1 is located at the same height as that of the interface between sealing member 8 and the surface of base member 1 facing insulating substrate 21, the detachment having occurred at outer end portion 31 of the adhesion surface is likely to be progressed to inner end portion 35 of the adhesion surface and then reach just below insulating substrate 21. When the detachment reaches just below insulating substrate 21, insulation failure of power module 101 may be caused.

In accordance with power module 101 according to the first embodiment, third surface 53 is inclined with respect to fourth surface 54 (see FIG. 3). That is, fourth surface 54, which is the interface between sealing member 8 and base member 1, is not connected straightly to third surface 53, which is the adhesion surface between adhesive member 12 and base member 1. Therefore, even when the detachment having occurred at outer end portion 31 of third surface 53, which is the adhesion surface between adhesive member 12 and base member 1, is progressed to inner end portion 35 of third surface 53 along a first arrow 32 as shown in FIG. 3, the detachment can be suppressed from being progressed to fourth surface 54, which is the interface between sealing member 8 and base member 1.

Further, inner end portion 35 of third surface 53, which is the adhesion surface between adhesive member 12 and base member 1, is located at a height different from that of fifth surface 55 facing second surface 52 of insulating substrate 21 (see FIG. 3). Therefore, even when the detachment having occurred at outer end portion 31 of the adhesion surface is progressed to inner end portion 35 of the adhesion surface, the detachment can be suppressed from reaching just below insulating substrate 21. Thus, insulation failure of power module 101 can be suppressed.

### Second Embodiment

Next, a configuration of a power module 101 according to a second embodiment will be described. The configuration of power module 101 according to the second embodiment is different from the configuration of power module 101 according to the first embodiment mainly in that a boundary surface 59 between first metal layer 22 and first joining layer 9 is located between inner end portion 35 and fifth surface 55 in the direction perpendicular to fifth surface 55, and the other configurations are substantially the same as the configurations of power module 101 according to the first embodiment. Hereinafter, the configuration different from the configuration of power module 101 according to the first embodiment will be mainly described.

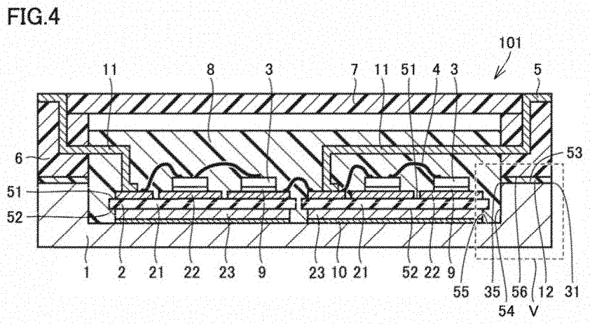

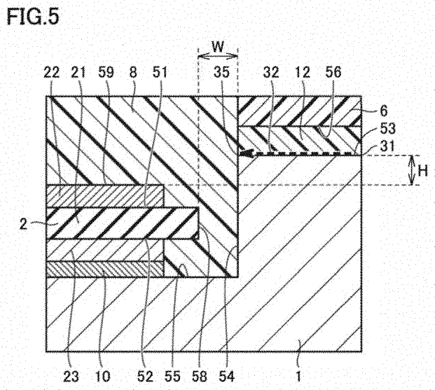

FIG. 4 is a schematic cross sectional view showing the configuration of power module 101 according to the second embodiment. FIG. 5 is an enlarged schematic cross sectional view of a region V in FIG. 4. As shown in FIG. 5, boundary surface 59 between first metal layer 22 and first joining layer 9 is located between inner end portion 35 and fifth surface 55. From another viewpoint, it can be said that inner end portion 35 is located higher than boundary surface 59. In the direction perpendicular to fifth surface 55, a distance between fifth surface 55 and inner end portion 35 is larger than a distance between fifth surface 55 and boundary surface 59.

In the direction perpendicular to fifth surface 55, a distance H between boundary surface 59 and inner end portion 35 is, for example, more than or equal to 0.4 mm and less than or equal to 20.0 mm. Insulating substrate 21 has an outer peripheral surface 58. Outer peripheral surface 58 is contiguous to each of first surface 51 and second surface 52. In a direction from inner end portion 35 toward outer end portion 31, a distance W between outer peripheral surface 58 and inner end portion 35 is, for example, less than or equal to 5 mm.

Next, functions and effects of power module 101 according to the second embodiment will be described.

When the mounting position of insulating substrate 21 is located further on the outer side and the distance between insulating substrate 21 and inner end portion 35 of the adhesion surface becomes shorter, an adhesion interface between insulating substrate 21 and sealing member 8 is located closer to inner end portion 35 of the adhesion surface. In that case, detachment having progressed at the interface between case member 6 and base member 1 may induce a crack in sealing member 8 and may reach insulating substrate 21.

In accordance with power module 101 according to the second embodiment, boundary surface 59 between first metal layer 22 and power semiconductor element 3 is located between inner end portion 35 and fifth surface 55 in the direction perpendicular to fifth surface 55. Therefore, the height of third surface 53, which is the adhesion surface between case member 6 and base member 1, is higher than the extension line along fifth surface 55 of base member 1 facing insulating substrate 21. Thus, a crack can be suppressed from being induced in sealing member 8, thereby suppressing insulation failure.

### Third Embodiment

Next, a configuration of a power module 101 according to a third embodiment will be described. The configuration of power module 101 according to the third embodiment is different from the configuration of power module 101 according to the first or second embodiment mainly in that case member 6 is provided with a first recess 70 and base member 1 has a first protrusion 60, and the other configurations are substantially the same as the configurations of power module 101 according to the first or second embodiment. Hereinafter, the configuration different from the configuration of power module 101 according to the first or second embodiment will be mainly described.

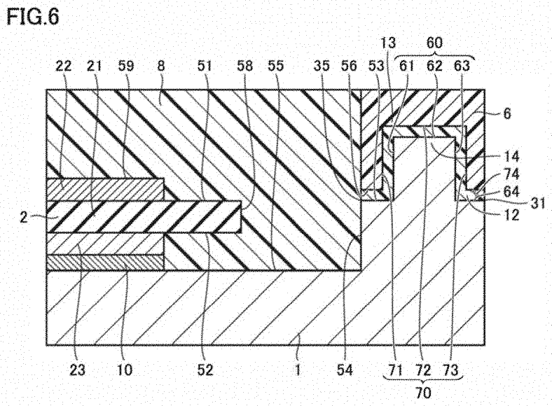

FIG. 6 is a schematic cross sectional view showing the configuration of power module 101 according to the third embodiment. The schematic cross sectional view shown in FIG. 6 corresponds to the region shown in FIG. 3 or FIG. 5. As shown in FIG. 6, case member 6 is provided with first recess 70. Base member 1 has first protrusion 60. First protrusion 60 is coupled to first recess 70. Adhesive member 12 is located between first recess 70 and first protrusion 60.

Base member 1 has a third surface 53, a first base surface 61, a second base surface 62, a third base surface 63, and a fourth base surface 64. First protrusion 60 is constituted of, for example, first base surface 61, second base surface 62, and third base surface 63. First base surface 61 is contiguous to third surface 53. First base surface 61 is inclined with respect to third surface 53. First base surface 61 extends in an upward direction from third surface 53. Second base surface 62 is contiguous to first base surface 61. Second base surface 62 is inclined with respect to first base surface 61. Second base surface 62 may be parallel to third surface 53, for example. It should be noted that the term “upward direction” is a direction parallel to a direction from second surface 52 toward first surface 51. On the other hand, the term “downward direction” is a direction parallel to a direction from first surface 51 toward second surface 52.

Third base surface 63 is contiguous to second base surface 62. Third base surface 63 is inclined with respect to second base surface 62. Third base surface 63 extends in the downward direction from second base surface 62. Third base surface 63 may be parallel to first base surface 61. Fourth base surface 64 is contiguous to third base surface 63. Fourth base surface 64 is inclined with respect to third base surface 63. Fourth base surface 64 may be parallel to second base surface 62. Fourth base surface 64 constitutes outer end portion 31.

Case member 6 has a sixth surface 56, a first case surface 71, a second case surface 72, a third case surface 73, and a fourth case surface 74. First recess 70 is constituted of, for example, first case surface 71, second case surface 72, and third case surface 73. First case surface 71 is contiguous to sixth surface 56. First case surface 71 is inclined with respect to sixth surface 56. First case surface 71 extends in the upward direction from sixth surface 56. Second case surface 72 is contiguous to first case surface 71. Second case surface 72 is inclined with respect to first case surface 71. Second case surface 72 may be parallel to sixth surface 56, for example.

Third case surface 73 is contiguous to second case surface 72. Third case surface 73 is inclined with respect to second case surface 72. Third case surface 73 extends in the downward direction from second case surface 72. Third case surface 73 may be parallel to first case surface 71. Fourth case surface 74 is contiguous to third case surface 73. Fourth case surface 74 is inclined with respect to third case surface 73. Fourth case surface 74 may be parallel to second case surface 72.

Third surface 53 faces sixth surface 56. First base surface 61 faces first case surface 71. Second base surface 62 faces second case surface 72. Third base surface 63 faces third case surface 73. Fourth base surface 64 faces fourth case surface 74. Adhesive member 12 is in contact with each of first base surface 61 and first case surface 71. Adhesive member 12 is in contact with each of second base surface 62 and second case surface 72. Adhesive member 12 is in contact with each of third base surface 63 and third case surface 73. Adhesive member 12 is in contact with each of fourth base surface 64 and fourth case surface 74.

Sixth surface 56 is located above third surface 53. Second case surface 72 is located above second base surface 62. Fourth case surface 74 is located above fourth base surface 64. Second case surface 72 is located above each of sixth surface 56 and fourth case surface 74. Second base surface 62 is located above each of third surface 53 and fourth base surface 64. Third case surface 73 is located on the outer side with respect to first case surface 71. Third base surface 63 is located on the outer side with respect to first base surface 61.

Next, functions and effects of power module 101 according to the third embodiment will be described.

In accordance with power module 101 according to the third embodiment, case member 6 is provided with first recess 70. Base member I has first protrusion 60. First protrusion 60 is coupled to first recess 70. Adhesive member 12 is located between first recess 70 and first protrusion 60. Therefore, in accordance with power module 101 according to the third embodiment, adhesion strength between base member 1 and case member 6 can be further improved by an anchor effect. Further, since an adhesion area can be increased, the adhesion strength between base member 1 and case member 6 can be further improved. Further, since a detachment path from outer end portion 31 to inner end portion 35 can be made long, detachment resistance between base member 1 and case member 6 can be further improved.

### Fourth Embodiment

Next, a configuration of a power module 101 according to a fourth embodiment will be described. The configuration of power module 101 according to the fourth embodiment is different from the configuration of power module 101 according to the first or second embodiment mainly in that case member 6 has a second protrusion 70 and base member 1 is provided with a second recess 60, and the other configurations are substantially the same as the configurations of power module 101 according to the first or second embodiment. Hereinafter, the configuration different from the configuration of power module 101 according to the first or second embodiment will be mainly described.

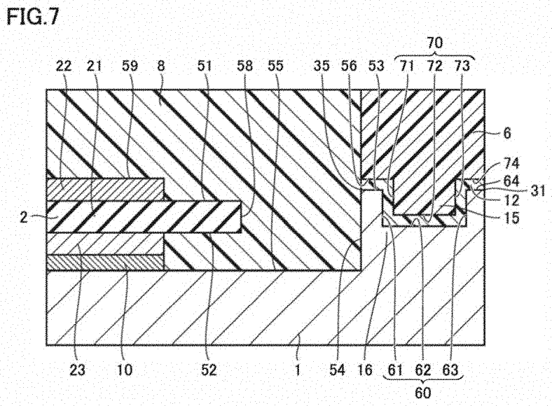

FIG. 7 is a schematic cross sectional view showing the configuration of power module 101 according to the fourth embodiment. The schematic cross sectional view shown in FIG. 7 corresponds to the region shown in FIG. 3 or FIG. 5. As shown in FIG. 7, case member 6 has second protrusion 70. Base member 1 is provided with second recess 60. Second protrusion 70 is coupled to second recess 60. Adhesive member 12 is located between second recess 60 and second protrusion 70.

Base member 1 has a third surface 53, a first base surface 61, a second base surface 62, a third base surface 63, and a fourth base surface 64. Second recess 60 is constituted of, for example, first base surface 61, second base surface 62, and third base surface 63. First base surface 61 is contiguous to third surface 53. First base surface 61 is inclined with respect to third surface 53. First base surface 61 extends in the downward direction from third surface 53. Second base surface 62 is contiguous to first base surface 61. Second base surface 62 is inclined with respect to first base surface 61. Second base surface 62 may be parallel to third surface 53, for example.

Third base surface 63 is contiguous to second base surface 62. Third base surface 63 is inclined with respect to second base surface 62. Third base surface 63 extends in the upward direction from second base surface 62. Third base surface 63 may be parallel to first base surface 61. Fourth base surface 64 is contiguous to third base surface 63. Fourth base surface 64 is inclined with respect to third base surface 63. Fourth base surface 64 may be parallel to second base surface 62. Fourth base surface 64 constitutes outer end portion 31. It should be noted that the term “upward direction” is a direction parallel to a direction from second surface 52 toward first surface 51. On the other hand, the term “downward direction” is a direction parallel to a direction from first surface 51 toward second surface 52.

Case member 6 has a sixth surface 56, a first case surface 71, a second case surface 72, a third case surface 73, and a fourth case surface 74. Second protrusion 70 is constituted of, for example, first case surface 71, second case surface 72, and third case surface 73. First case surface 71 is contiguous to sixth surface 56. First case surface 71 is inclined with respect to sixth surface 56. First case surface 71 extends in the downward direction from sixth surface 56. Second case surface 72 is contiguous to first case surface 71. Second case surface 72 is inclined with respect to first case surface 71. Second case surface 72 may be parallel to sixth surface 56, for example.

Third case surface 73 is contiguous to second case surface 72. Third case surface 73 is inclined with respect to second case surface 72. Third case surface 73 extends in the upward direction from second case surface 72. Third case surface 73 may be parallel to first case surface 71. Fourth case surface 74 is contiguous to third case surface 73. Fourth case surface 74 is inclined with respect to third case surface 73. Fourth case surface 74 may be parallel to second case surface 72.

Third surface 53 faces sixth surface 56. First base surface 61 faces first case surface 71. Second base surface 62 faces second case surface 72. Third base surface 63 faces third case surface 73. Fourth base surface 64 faces fourth case surface 74. Adhesive member 12 is in contact with each of first base surface 61 and first case surface 71. Adhesive member 12 is in contact with each of second base surface 62 and second case surface 72. Adhesive member 12 is in contact with each of third base surface 63 and third case surface 73. Adhesive member 12 is in contact with each of fourth base surface 64 and fourth case surface 74.

Sixth surface 56 is located above third surface 53. Second case surface 72 is located above second base surface 62. Fourth case surface 74 is located above fourth base surface 64. Second case surface 72 is located below each of sixth surface 56 and fourth case surface 74. Second base surface 62 is located below each of third surface 53 and fourth base surface 64. Third case surface 73 is located on the outer side with respect to first case surface 71. Third base surface 63 is located on the outer side with respect to first base surface 61.

Next, functions and effects of power module 101 according to the fourth embodiment will be described.

In accordance with power module 101 according to the fourth embodiment, case member 6 has second protrusion 70. Base member 1 is provided with second recess 60. Second protrusion 70 is coupled to second recess 60. Adhesive member 12 is located between second recess 60 and second protrusion 70. Therefore, in accordance with power module 101 according to the third embodiment, adhesion strength between base member 1 and case member 6 can be further improved by an anchor effect. Further, since an adhesion area can be increased, the adhesion strength between base member 1 and case member 6 can be further improved. Further, since a detachment path from outer end portion 31 to inner end portion 35 can be made long, detachment resistance between base member 1 and case member 6 can be further improved.

### Fifth Embodiment

Next, a configuration of a power module 101 according to a fifth embodiment will be described. The configuration of power module 101 according to the fifth embodiment is different from the configuration of power module 101 according to the third embodiment mainly in that the recess of case member 6 and the protrusion of base member 1 are coupled to each other in the lateral direction, and the other configurations are substantially the same as the configurations of power module 101 according to the third embodiment. Hereinafter, the configuration different from the configuration of power module 101 according to the third embodiment will be mainly described.

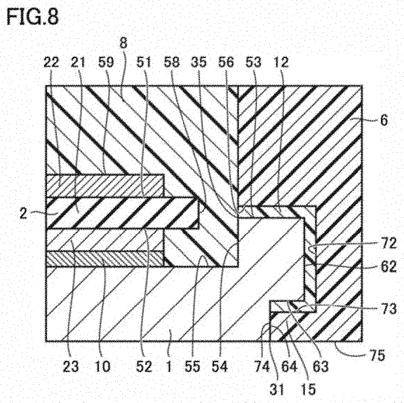

FIG. 8 is a schematic cross sectional view showing the configuration of power module 101 according to the fifth embodiment. The schematic cross sectional view shown in FIG. 8 corresponds to the region shown in FIG. 6. As shown in FIG. 8, case member 6 is provided with a recess. Base member 1 has a protrusion. The recess of case member 6 and the protrusion of base member 1 are coupled to each other in the lateral direction.

Base member 1 has a third surface 53, a second base surface 62, a third base surface 63, and a fourth base surface 64. The protrusion is constituted of, for example, third surface 53, second base surface 62, and third base surface 63. Second base surface 62 is contiguous to third surface 53. Second base surface 62 is inclined with respect to third surface 53. Second base surface 62 extends in the downward direction from third surface 53.

Third base surface 63 is contiguous to second base surface 62. Third base surface 63 is inclined with respect to second base surface 62. Third base surface 63 extends from second base surface 62 toward the inner side. Third base surface 63 may be parallel to third surface 53. Fourth base surface 64 is contiguous to third base surface 63. Fourth base surface 64 is inclined with respect to third base surface 63. Fourth base surface 64 may be parallel to second base surface 62. Fourth base surface 64 constitutes outer end portion 31.

Case member 6 has a sixth surface 56, a second case surface 72, a third case surface 73, a fourth case surface 74, and a fifth case surface 75. The recess is constituted of, for example, sixth surface 56, second case surface 72, and third case surface 73. Second case surface 72 is contiguous to sixth surface 56. Second case surface 72 is inclined with respect to sixth surface 56. Second case surface 72 extends in the downward direction from sixth surface 56.

Third case surface 73 is contiguous to second case surface 72. Third case surface 73 is inclined with respect to second case surface 72. Third case surface 73 extends from second case surface 72 to the inner side. Third case surface 73 may be parallel to sixth surface 56. Fourth case surface 74 is contiguous to third case surface 73. Fourth case surface 74 is inclined with respect to third case surface 73. Fourth case surface 74 may be parallel to second case surface 72. Fifth case surface 75 is contiguous to fourth case surface 74. Fifth case surface 75 is inclined with respect to fourth case surface 74. Fifth case surface 75 may be parallel to third case surface 73. Fifth case surface 75 constitutes a portion of the rear surface of power module 101.

Third surface 53 faces sixth surface 56. Second base surface 62 faces second case surface 72. Third base surface 63 faces third case surface 73. Fourth base surface 64 faces fourth case surface 74. Adhesive member 12 is in contact with each of second base surface 62 and second case surface 72. Adhesive member 12 is in contact with each of third base surface 63 and third case surface 73. Adhesive member 12 is in contact with each of fourth base surface 64 and fourth case surface 74. Fifth case surface 75 is separated from adhesive member 12.

Fifth surface 55 is located between third surface 53 and third base surface 63 in the direction perpendicular to fifth surface 55. Similarly, fifth surface 55 is located between sixth surface 56 and third case surface 73 in the direction perpendicular to fifth surface 55. Sixth surface 56 is located above third surface 53. Second case surface 72 is located on the outer side with respect to second base surface 62. Third case surface 73 is located below third base surface 63.

Next, functions and effects of power module 101 according to the fifth embodiment will be described.

In accordance with power module 101 according to the fifth embodiment, the protrusion of base member 1 and the recess of case member 6 are coupled to each other in a state in which case member 6 surrounds second base surface 62, which is the outer peripheral side surface of base member 1. Therefore, outer end portion 31 of adhesive member 12 is located on the bottom surface of power module 101, rather than the outer peripheral side surface of power module 101. Therefore, even when tensile stress is generated due to warpage of power module 101, the warpage of power module 101 can be suppressed by the protrusion formed by third case surface 73, fourth case surface 74, and fifth case surface 75 of case member 6. Therefore, detachment between base member 1 and case member 6 can be suppressed. As a result, detachment resistance between base member 1 and case member 6 can be further improved. Thus, insulation failure of power module 101 can be suppressed.

### Sixth Embodiment

Next, a configuration of a power module 101 according to a sixth embodiment will be described. The configuration of power module 101 according to the sixth embodiment is different from the configuration of power module 101 according to the first or second embodiment mainly in that a groove portion 80 is provided in inner peripheral surface 50 of base member 1, and the other configurations are substantially the same as the configurations of power module 101 according to the first or second embodiment. Hereinafter, the configuration different from the configuration of power module 101 according to the first or second embodiment will be mainly described.

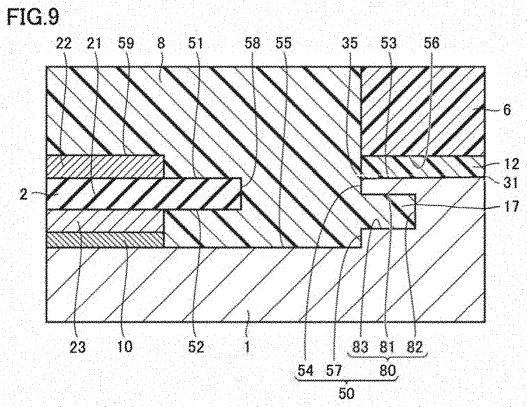

FIG. 9 is a schematic cross sectional view showing the configuration of power module 101 according to the sixth embodiment. The schematic cross sectional view shown in FIG. 9 corresponds to the region shown in FIG. 3 or FIG. 5. As shown in FIG. 9, the base member has an inner peripheral surface 50. Inner peripheral surface 50 surrounds insulating substrate 21 when viewed in the direction perpendicular to first surface 51. Inner peripheral surface 50 is provided with groove portion 80. Groove portion 80 is provided in the whole of inner peripheral surface 50. Groove portion 80 has a shape of loop. A portion of sealing member 8 is present in groove portion 80.

Inner peripheral surface 50 has a fourth surface 54, a first inner peripheral region 81, a second inner peripheral region 82, a third inner peripheral region 83, and a seventh surface 57. Groove portion 80 is constituted of, for example, first inner peripheral region 81, second inner peripheral region 82, and third inner peripheral region 83. First inner peripheral region 81 is contiguous to fourth surface 54. First inner peripheral region 81 is inclined with respect to fourth surface 54. First inner peripheral region 81 extends from fourth surface 54 toward the outer side. Second inner peripheral region 82 is contiguous to first inner peripheral region 81. Second inner peripheral region 82 is inclined with respect to first inner peripheral region 81. Second inner peripheral region 82 may be parallel to fourth surface 54, for example.

Third inner peripheral region 83 is contiguous to second inner peripheral region 82. Third inner peripheral region 83 is inclined with respect to second inner peripheral region 82. Third inner peripheral region 83 extends from second inner peripheral region 82 toward the inner side. Third inner peripheral region 83 may be parallel to first inner peripheral region 81. Seventh surface 57 is contiguous to third inner peripheral region 83. Seventh surface 57 is inclined with respect to third inner peripheral region 83. Seventh surface 57 may be parallel to second inner peripheral region 82. Seventh surface 57 is contiguous to fifth surface 55. Seventh surface 57 is inclined with respect to fifth surface 55. Fifth surface 55 may be parallel to third inner peripheral region 83.

Fourth surface 54 is located above seventh surface 57. First inner peripheral region 81 is located above third inner peripheral region 83. Second inner peripheral region 82 is located on the outer side with respect to each of fourth surface 54 and seventh surface 57. Sealing member 8 is in contact with each of first inner peripheral region 81, second inner peripheral region 82, and third inner peripheral region 83. Second inner peripheral region 82 may face outer peripheral surface 58 of insulating substrate 21.

Next, functions and effects of power module 101 according to the sixth embodiment will be described.

In accordance with power module 101 according to the sixth embodiment, groove portion 80 is provided in inner peripheral surface 50 of base member 1 and the portion of sealing member 8 is present in groove portion 80. Therefore, in accordance with power module 101 according to the sixth embodiment, even when a large warpage occurs in power module 101 and tensile stress becomes large, adhesion strength between base member 1 and sealing member 8 can be improved by an anchor effect of sealing member 8 present in groove portion 80. Further, since groove portion 80 is provided in inner peripheral surface 50, the interface between inner peripheral surface 50 of base member 1 and sealing member 8 becomes large. Therefore, detachment can be suppressed from being progressed along inner peripheral surface 50 of base member 1.

### Seventh Embodiment

Next, a configuration of a power module 101 according to a seventh embodiment will be described. The configuration of power module 101 according to the seventh embodiment is different from the configuration of power module 101 according to the third embodiment mainly in that groove portion 80 is provided in inner peripheral surface 50 of base member 1, and the other configurations are substantially the same as the configurations of power module 101 according to the third embodiment. Hereinafter, the configuration different from the configuration of power module 101 according to the third embodiment will be mainly described.

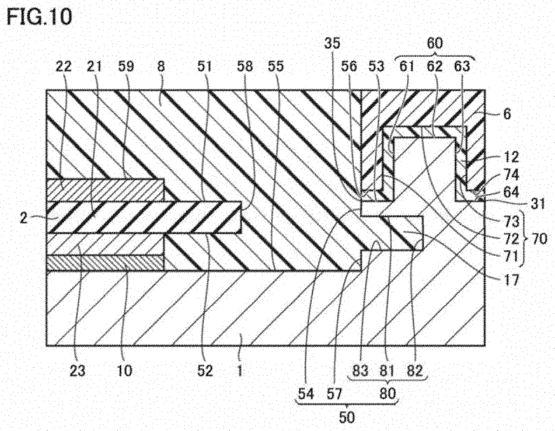

FIG. 10 is a schematic cross sectional view showing the configuration of power module 101 according to the seventh embodiment. The schematic cross sectional view shown in FIG. 10 corresponds to the region shown in FIG. 6. As shown in FIG. 10, base member I has an inner peripheral surface 50. Inner peripheral surface 50 surrounds insulating substrate 21 when viewed in the direction perpendicular to first surface 51. Inner peripheral surface 50 is provided with groove portion 80. Groove portion 80 is provided in the whole of inner peripheral surface 50. Groove portion 80 has a shape of loop. A portion of sealing member 8 is present in groove portion 80.

Inner peripheral surface 50 has a fourth surface 54, a first inner peripheral region 81, a second inner peripheral region 82, a third inner peripheral region 83, and a seventh surface 57. Groove portion 80 is constituted of, for example, first inner peripheral region 81, second inner peripheral region 82, and third inner peripheral region 83. The configuration of groove portion 80 in power module 101 according to the seventh embodiment is the same as the configuration of groove portion 80 in power module 101 according to the sixth embodiment.

Second inner peripheral region 82 is located between first base surface 61 and third base surface 63 in the direction parallel to fifth surface 55. Similarly, second inner peripheral region 82 is located between first case surface 71 and third case surface 73 in the direction parallel to fifth surface 55. Functions and effects of power module 101 according to the seventh embodiment are the same as those of power module 101 according to the sixth embodiment.

### Eighth Embodiment

Next, a configuration of a power module 101 according to an eighth embodiment will be described. The configuration of power module 101 according to the eighth embodiment is different from the configuration of power module 101 according to the fourth embodiment mainly in that groove portion 80 is provided in inner peripheral surface 50 of base member 1, and the other configurations are substantially the same as the configurations of power module 101 according to the fourth embodiment. Hereinafter, the configuration different from the configuration of power module 101 according to the fourth embodiment will be mainly described.

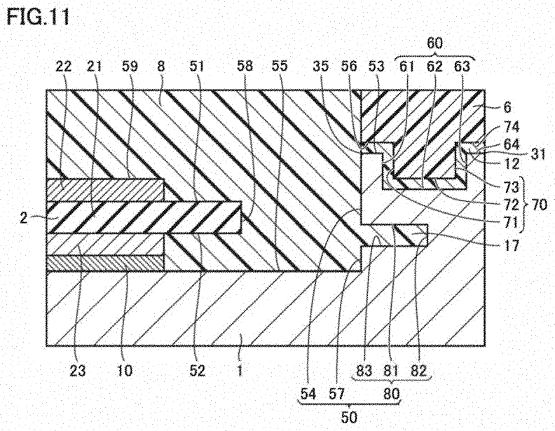

FIG. 11 is a schematic cross sectional view showing the configuration of power module 101 according to the eighth embodiment. The schematic cross sectional view shown in FIG. 11 corresponds to the region shown in FIG. 7. As shown in FIG. 11, base member 1 has an inner peripheral surface 50. Inner peripheral surface 50 surrounds insulating substrate 21 when viewed in the direction perpendicular to first surface 51. Inner peripheral surface 50 is provided with groove portion 80. Groove portion 80 is provided in the whole of inner peripheral surface 50. Groove portion 80 has a shape of loop. A portion of sealing member 8 is present in groove portion 80.

Inner peripheral surface 50 has a fourth surface 54, a first inner peripheral region 81, a second inner peripheral region 82, a third inner peripheral region 83, and a. seventh surface 57. Groove portion 80 is constituted of, for example, first inner peripheral region 81, second inner peripheral region 82, and third inner peripheral region 83. The configuration of groove portion 80 in power module 101 according to the eighth embodiment is the same as the configuration of groove portion 80 in power module 101 according to the sixth embodiment.

Second inner peripheral region 82 is located between first base surface 61 and third base surface 63 in the direction parallel to fifth surface 55. Similarly, second inner peripheral region 82 is located between first case surface 71 and third case surface 73 in the direction parallel to fifth surface 55. Functions and effects of power module 101 according to the eighth embodiment are the same as those of power module 101 according to the sixth embodiment.

### Ninth Embodiment

Next, the configuration of power module 101 according to the ninth embodiment will be described. The configuration of power module 101 according to the ninth embodiment is different from the configuration of power module 101 according to the fifth embodiment mainly in that groove portion 80 is provided in inner peripheral surface 50 of base member 1, and the other configurations are substantially the same as the configurations of power module 101 according to the fifth embodiment.

Hereinafter, the configuration different from the configuration of power module 101 according to the fifth embodiment will be mainly described.

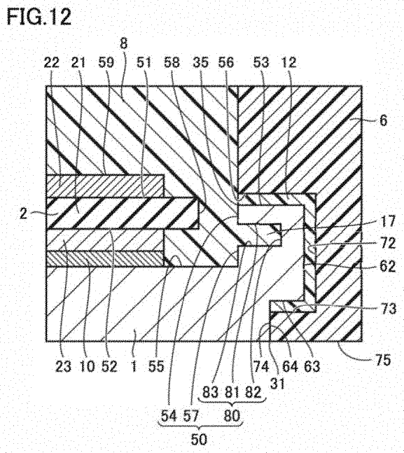

FIG. 12 is a schematic cross sectional view showing the configuration of power module 101 according to the ninth embodiment. The schematic cross sectional view shown in FIG. 12 corresponds to the region shown in FIG. 8. As shown in FIG. 12, base member 1 has an inner peripheral surface 50. Inner peripheral surface 50 surrounds insulating substrate 21 when viewed in the direction perpendicular to first surface 51. Inner peripheral surface 50 is provided with groove portion 80. Groove portion 80 is provided in the whole of inner peripheral surface 50. Groove portion 80 has a shape of loop. A portion of sealing member 8 is present in groove portion 80.

Inner peripheral surface 50 has a fourth surface 54, a first inner peripheral region 81, a second inner peripheral region 82, a third inner peripheral region 83, and a seventh surface 57. Groove portion 80 is constituted of, for example, first inner peripheral region 81, second inner peripheral region 82, and third inner peripheral region 83. The configuration of groove portion 80 in power module 101 according to the eighth embodiment is the same as the configuration of groove portion 80 in power module 101 according to the sixth embodiment.

Second inner peripheral region 82 is located on the inner side with respect to second base surface 62 in the direction parallel to fifth surface 55. In the direction perpendicular to fifth surface 55, each of first inner peripheral region 81 and third inner peripheral region 83 is located between third surface 53 and third base surface 63. In the direction perpendicular to fifth surface 55, each of first inner peripheral region 81 and third inner peripheral region 83 is located between sixth surface 56 and third case surface 73. Functions and effects of power module 101 according to the eighth embodiment are the same as those of power module 101 according to the sixth embodiment.

### Tenth Embodiment

Next, a configuration of a power conversion device according to a tenth embodiment will be described. The power conversion device according to the tenth embodiment is a power conversion device to which any one of power modules 101 according to the first to ninth embodiments is applied. Although power conversion device 200 according to the tenth embodiment is not particularly limited, the following describes a case where power conversion device 200 is a three-phase inverter.

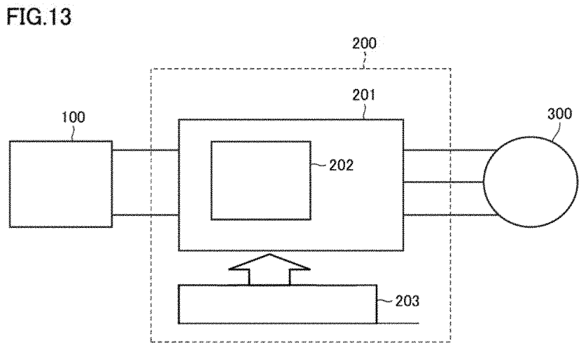

FIG. 13 is a block diagram showing a configuration of a power conversion system including the power conversion device according to the tenth embodiment. As shown in FIG. 13, the power conversion system includes a power supply 100, power conversion device 200, and a load 300. Power supply 100 is a DC power supply, and supplies DC power to power conversion device 200. Power supply 100 is not particularly limited, and may be constituted of, for example, a DC system, a solar battery, or a power storage battery, or may be constituted of a rectifier circuit or AC/DC converter connected to an AC system. Power supply 100 may be constituted of a DC/DC converter that converts DC power output from the DC system into another DC power.

Power conversion device 200 is a three-phase inverter connected between power supply 100 and load 300, converts the DC power supplied from power supply 100 into AC power, and supplies the AC power to load 300. As shown in FIG. 13, power conversion device 200 includes: a main conversion circuit 201 that converts DC power into AC power and that outputs the AC power; and a control circuit 203 that outputs, to main conversion circuit 201, a control signal for controlling main conversion circuit 201.

Load 300 is a three-phase electric motor driven by the AC power supplied from power conversion device 200. It should be noted that although not particularly limited, load 300 is an electric motor mounted on various types of electric devices, and is used as an electric motor for a hybrid vehicle, an electric vehicle, a railroad vehicle, an elevator, or an air conditioner, for example.

Hereinafter, details of power conversion device 200 will be described. Main conversion circuit 201 includes a switching element (not shown) and a reflux diode (not shown). When the switching element switches voltage supplied from power supply 100, main conversion circuit 201 converts DC power supplied from power supply 100 into AC power and supplies the AC power to load 300. Although there are various specific circuit configurations for main conversion circuit 201, main conversion circuit 201 according to the present embodiment is a two-level three-phase full bridge circuit, and can be constituted of six switching elements and six reflux diodes antiparallel to the respective switching elements. Any one of power modules 101 according to the first to ninth embodiments is applied to at least one of the switching elements and the reflux diodes of main conversion circuit 201. Every two switching elements of the six switching elements are connected in series to form an upper/lower arm, and the upper/lower arms form respective phases (U phase, V phase, and W phase) of the full bridge circuit. Output terminals of the upper/lower arms, i.e., three output terminals of main conversion circuit 201 are connected to load 300.

Further, main conversion circuit 201 includes a driving circuit (not shown) that drives each of the switching elements. The driving circuit may be included in a semiconductor module 202 or may be provided separately from semiconductor module 202. The driving circuit generates a driving signal for driving a switching element included in main conversion circuit 201, and supplies the driving signal to the control electrode of the switching element of main conversion circuit 201. Specifically, in accordance with the control signal from control circuit 203, the driving circuit outputs, to the control electrode of each switching element, a driving signal for bringing the switching element into the ON state and a driving signal for bringing the switching element into the OFF state. In the case of maintaining the switching element in the ON state, the driving signal is a voltage signal (ON signal) more than or equal to a threshold voltage of the switching element, whereas in the case of maintaining the switching element in the OFF state, the driving signal is a voltage signal (OFF signal) less than or equal to than the threshold voltage of the switching element.

Control circuit 203 controls the switching elements of main conversion circuit 201 to supply desired power to load 300. Specifically, a period of time (ON time) during which each switching element of main conversion circuit 201 should be in the ON state is calculated based on the power to be supplied to load 300. For example, main conversion circuit 201 can be controlled by pulse width modulation (PWM) control in which the ON time of the switching element is modulated in accordance with voltage to be output. Then, a control command (control signal) is output to the driving circuit included in main conversion circuit 201 so as to output an ON signal to a switching element that should be brought into the ON state at each time point and so as to output an OFF signal to a switching element to be brought into the OFF state at each time point. In accordance with the control signal, the driving circuit outputs the ON signal or the OFF signal as the driving signal to the control electrode of each switching element.

In power conversion device 200 according to the present embodiment, any one of power modules 101 according to the first to ninth embodiments is applied as semiconductor module 202 included in main conversion circuit 201. Therefore, power conversion device 200 according to the present embodiment has improved reliability.

In the present embodiment, it has been illustratively described that the present disclosure is applied to the two-level three-phase inverter; however, the present disclosure is not limited to this, and can be applied to various power conversion devices. Although the two-level power conversion device is employed in the present embodiment, a three-level power conversion device or a multi-level power conversion device may be employed. When the power conversion device supplies power to a single-phase load, the present disclosure may be applied to a single-phase inverter. When the power conversion device supplies power to a DC load or the like, the present disclosure may be applied to a DC/DC converter or an AC/DC converter.

The power conversion device to which the present disclosure is applied is not limited to the case where the load is an electric motor, and may be incorporated in a power supply device for an electric discharge machine or laser machine, or a power supply device for an induction heating cooker or non-contact power supply system, for example. The power conversion device to which the present disclosure is applied can be used as a power conditioner for a photovoltaic power generation system, a power storage system, or the like.

The first to tenth embodiments disclosed herein are illustrative and non-restrictive in any respect. At least two of the first to tenth embodiments disclosed herein may be combined as long as there is no contradiction. The scope of the present application is defined by the terms of the claims, rather than the embodiments described above, and is intended to include any modifications within the scope and meaning equivalent to the terms of the claims.

### REFERENCE SIGNS LIST

1: base member; 3; power semiconductor element; 4: bonding wire; 5: external terminal; 6: case member; 7: cover member; 8: sealing member; 9: first joining layer; 10: second joining layer; 11: main electrode; 12: adhesive member; 21: insulating substrate; 22: first metal layer; 23: second metal layer; 31: outer end portion; 32: first arrow; 33: second arrow; 35: inner side end portion; 50: inner peripheral surface; 51: first surface; 52: second surface; 53: third surface; 54: fourth surface; 55: fifth surface; 56: sixth surface; 57: seventh surface; 58: outer peripheral surface; 59: boundary surface; 60: first protrusion, second recess; 61: first base surface; 62: second base surface; 63: third base surface; 64: fourth base surface; 70: first protrusion, second recess; 71: first case surface; 72: second case surface; 73: third case surface; 74: fourth case surface; 75: fifth case surface; 80: groove portion; 81: first inner peripheral region; 82: second inner peripheral region; 83: third inner peripheral region; 100: power supply; 101: power module; 200: power conversion device; 201: main conversion circuit; 202: semiconductor module; 203: control circuit; 300: load; H: distance; W: gap.

1. A power module comprising:
an insulating substrate having a first surface and a second surface opposite to the first surface;
a case member that surrounds the insulating substrate when viewed in a direction perpendicular to the first surface;
a power semiconductor element that faces the first surface;
a base member that faces the second surface;
a sealing member that seals the power semiconductor element and the insulating substrate and that is in contact with the case member; and
an adhesive member that fixes the base member and the case member and that surrounds the insulating substrate when viewed in the direction perpendicular to the first surface, wherein
the base member has a third surface that is in contact with the adhesive member, a fourth surface that is contiguous to the third surface and that is in contact with the sealing member, and a fifth surface that faces the second surface,
in a direction perpendicular to the fifth surface, an inner end portion of the third surface is located at a height different from a height of the fifth surface, and
the third surface is inclined with respect to the fourth surface.

2. The power module according to claim 1, further comprising a joining layer provided between the first surface and the power semiconductor element, wherein
in the direction perpendicular to the fifth surface, a boundary surface between the joining layer and the power semiconductor element is located between the inner end portion and the fifth surface.

3. The power module according to claim 1, wherein
the case member is provided with a recess,
the base member has a protrusion coupled to the recess, and
the adhesive member is located between the recess and the protrusion.

4. The power module according to claim 1, wherein
the case member has a protrusion,
the base member is provided with a recess coupled to the protrusion, and
the adhesive member is located between the protrusion and the recess.

5. The power module according to claim 1, wherein
the base member has an inner peripheral surface that surrounds the insulating substrate when viewed in the direction perpendicular to the first surface,
a groove portion is provided in the inner peripheral surface, and
a portion of the sealing member is presented in the groove portion.

6. A power conversion device comprising:
a main conversion circuit that has the power module according to claim 1 and that converts input power and outputs the converted power; and
a control circuit that outputs, to the main conversion circuit, a control signal for controlling the main conversion circuit.
